(19) United States
(12) Patent Application Publication
(10) Pub. No.: US 2010/0053817 A1
(43) Pub. Date: Mar. 4, 2010

(54) COATED MAGNETIC HEAD AND METHODS FOR FABRICATION THEREOF

(76) Inventors: Robert Glenn Biskeborn, Hollister, CA (US); Calvin Shyhjong Lo, Saratoga, CA (US); Andrew C. Ting, El Prado, NM (US)

Correspondence Address: ZILKA-KOTAB, PC- IBM, P.O. BOX 721120, SAN JOSE, CA, 95172-1120, US

(21) Appl. No.: 12/204,671

(22) Filed: Sep. 4, 2008

(51) Int. Cl. G11B 5/33; C23C 14/00; B05D 5/00

(52) U.S. Cl. 360/313; 427/127; 427/595; G9B/5.104

(57) ABSTRACT

In one general embodiment, a magnetic head includes a module having a substrate and a gap, the gap having an array of transducers therein, wherein the gap is recessed from a plane extending across a tape bearing surface side of the substrate; and a coating of aluminum oxide above at least a tape bearing surface side of the gap, the aluminum oxide having polycrystalline portions and amorphous portions.

### BACKGROUND

The present invention relates to data storage systems, and more particularly, this invention relates to magnetic tape heads.

In magnetic storage systems, data is read from and written onto magnetic recording media utilizing magnetic transducers commonly. Data is written on the magnetic recording media by moving a magnetic recording transducer to a position over the media where the data is to be stored. The magnetic recording transducer then generates a magnetic field, which encodes the data into the magnetic media. Data is read from the media by similarly positioning the magnetic read transducer and then sensing the magnetic field of the magnetic media. Read and write operations may be independently synchronized with the movement of the media to ensure that the data can be read from and written to the desired location on the media.

An important and continuing goal in the data storage industry is that of increasing the density of data stored on a medium. For tape storage systems, that goal has lead to increasing the track density on recording tape, and decreasing the thickness of the magnetic tape medium. However, the development of small footprint, higher performance tape drive systems has created various problems in the design of a tape head assembly for use in such systems.

As an example of one of the problems encountered, it is believed that prior to discovery of the teachings herein, it had been impossible to implement GMR or TMR sensors in a multi-sensor tape head in a way that was adequate for today's data-storage needs. Reasons for the failure to create a useful working embodiment include, but are not limited to, corrosion, wear, spacing loss, shorting and head-tape stiction.

The following description presents the culmination of over three years of research aimed at discovery of the novel processes and systems disclosed herein.

### SUMMARY

In one general embodiment, a magnetic head includes a module having a substrate and a gap, the gap having an array of transducers therein, wherein the gap is recessed from a plane extending across a tape bearing surface side of the substrate; and a coating of aluminum oxide above at least a tape bearing surface side of the gap, the aluminum oxide having polycrystalline portions and amorphous portions.

In another general embodiment, a magnetic head includes a module having a substrate, a gap, and a closure coupled to the gap on an opposite side thereof than the substrate, the gap having an array of GMR or TMR sensors therein, wherein the gap is recessed from a plane extending across a tape bearing surface side of the substrate; and a coating of aluminum oxide above at least a tape bearing surface side of the gap, the aluminum oxide having polycrystalline portions and amorphous portions, wherein the gap is recessed about 10 to about 50 nanometers, wherein a ratio of oxygen to aluminum in the aluminum oxide is about 3 to 2 to about 3.5 to 2, wherein the coating has less than about 1% atomic percent of impurities that are not aluminum and oxygen, wherein a thickness of the coating above the tape bearing surface side of the gap is about 20 to about 60 nanometers.

In another general embodiment, a tape-based data storage system includes forming a module having a substrate, a gap, and a closure coupled to the gap on an opposite side thereof than the substrate, the gap having an array of GMR or TMR sensors therein, recessing the gap from a tape bearing surface side of the substrate; depositing a coating of aluminum oxide above tape bearing surface sides of the gap, module and closure to a thickness of between about 10 and about 50 nanometers under conditions that form a layer of aluminum oxide having polycrystalline portions and amorphous portions; and recessing the coating to a thickness of 0 to about 20 nanometers above the tape bearing surface side of the substrate.

In yet another general embodiment, a method includes forming a module having a substrate, a gap, and a closure coupled to the gap on an opposite side thereof than the substrate, the gap having an array of GMR or TMR sensors therein; recessing the gap about 20 to about 40 nanometers from a plane extending across a tape bearing surface side of the substrate; depositing a coating of aluminum oxide above tape bearing surface sides of the gap, module and closure to a thickness of between about 10 and about 50 nanometers under conditions that form a layer of aluminum oxide having polycrystalline portions and amorphous portions; recessing the coating to a thickness of 0 to about 20 nanometers above the tape bearing surface side of the substrate, wherein a ratio of oxygen to aluminum in the aluminum oxide is about 3 to 2 to about 3.5 to 2, wherein the coating has less than about 1% atomic percent of impurities that are not aluminum and oxygen.

Any of these embodiments may be implemented in a magnetic data storage system such as a tape drive system, which may include a magnetic head, a drive mechanism for passing a magnetic medium (e.g., recording tape) over the magnetic head, and a controller electrically coupled to the magnetic head.

Other aspects and embodiments of the present invention will become apparent from the following detailed description, which, when taken in conjunction with the drawings, illustrate by way of example the principles of the invention.

### BRIEF DESCRIPTION OF THE SEVERAL VIEWS OF THE DRAWINGS

FIG. 1 is a schematic diagram of a simplified tape drive system according to one embodiment.

FIG. 2 illustrates a side view of a flat-lapped, bi-directional, two-module magnetic tape head according to one embodiment.

FIG. 2A is a tape bearing surface view taken from Line 2A of FIG. 2.

FIG. 2B is a detailed view taken from Circle 2B of FIG. 2A.

FIG. 2C is a detailed view of a partial tape bearing surface of a pair of modules.

FIGS. 3A-3D are schematic views of a portion of a magnetic head, including a gap between a closure and a substrate, during steps in a processing sequence.

FIG. 4 is a flow chart of a method according to one embodiment.

### DETAILED DESCRIPTION

The following description is made for the purpose of illustrating the general principles of the present invention and is not meant to limit the inventive concepts claimed herein. Further, particular features described herein can be used in combination with other described features in each of the various possible combinations and permutations.

Unless otherwise specifically defined herein, all terms are to be given their broadest possible interpretation including meanings implied from the specification as well as meanings understood by those skilled in the art and/or as defined in dictionaries, treatises, etc.

It must also be noted that, as used in the specification and the appended claims, the singular forms “a,” “an” and “the” include plural referents unless otherwise specified.

The following description discloses several preferred embodiments of tape-based storage systems, as well as operation and/or component parts thereof.

In one general embodiment, a magnetic head includes a module having a substrate and a gap, the gap having an array of transducers therein, wherein the gap is recessed from a plane extending across a tape bearing surface side of the substrate; and a coating of aluminum oxide above at least a tape bearing surface side of the gap, the aluminum oxide having polycrystalline portions and amorphous portions.

In another general embodiment, a magnetic head includes a module having a substrate, a gap, and a closure coupled to the gap on an opposite side thereof than the substrate, the gap having an array of GMR or TMR sensors therein, wherein the gap is recessed from a plane extending across a tape bearing surface side of the substrate; and a coating of aluminum oxide above at least a tape bearing surface side of the gap, the aluminum oxide having polycrystalline portions and amorphous portions, wherein the gap is recessed about 10 to about 50 nanometers, wherein a ratio of oxygen to aluminum in the aluminum oxide is about 3 to 2 to about 3.5 to 2, wherein the coating has less than about 1% atomic percent of impurities that are not aluminum and oxygen, wherein a thickness of the coating above the tape bearing surface side of the gap is about 20 to about 60 nanometers.

In another general embodiment, a tape-based data storage system includes forming a module having a substrate, a gap, and a closure coupled to the gap on an opposite side thereof than the substrate, the gap having an array of GMR or TMR sensors therein, recessing the gap from a tape bearing surface side of the substrate; depositing a coating of aluminum oxide above tape bearing surface sides of the gap, module and closure to a thickness of between about 10 and about 50 nanometers under conditions that form a layer of aluminum oxide having polycrystalline portions and amorphous portions; and recessing the coating to a thickness of 0 to about 20 nanometers above the tape bearing surface side of the substrate.

In yet another general embodiment, a method includes forming a module having a substrate, a gap, and a closure coupled to the gap on an opposite side thereof than the substrate, the gap having an array of GMR or TMR sensors therein; recessing the gap about 20 to about 40 nanometers from a plane extending across a tape bearing surface side of the substrate; depositing a coating of aluminum oxide above tape bearing surface sides of the gap, module and closure to a thickness of between about 10 and about 50 nanometers under conditions that form a layer of aluminum oxide having polycrystalline portions and amorphous portions; recessing the coating to a thickness of 0 to about 20 nanometers above the tape bearing surface side of the substrate, wherein a ratio of oxygen to aluminum in the aluminum oxide is about 3 to 2 to about 3.5 to 2, wherein the coating has less than about 1% atomic percent of impurities that are not aluminum and oxygen.

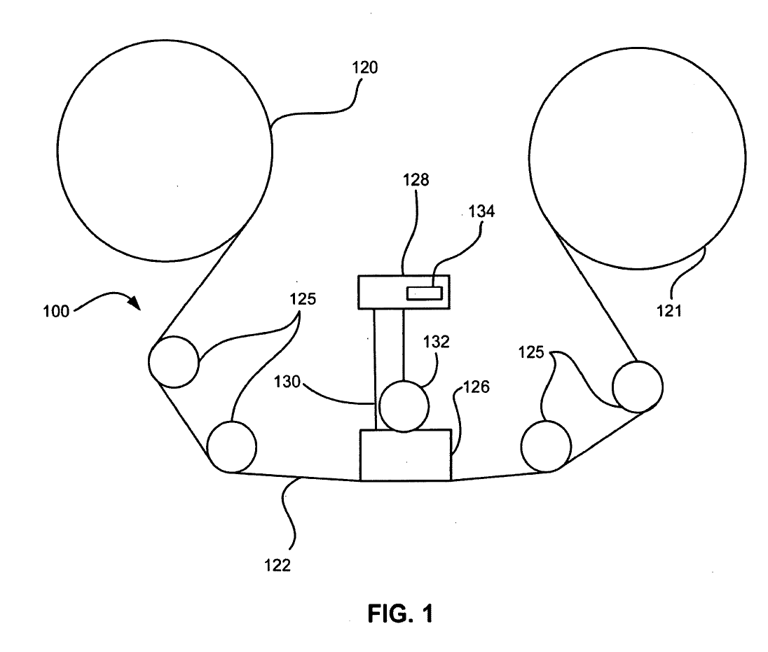

FIG. 1 illustrates a simplified tape drive 100 of a tape-based data storage system, which may be employed in the context of the present invention. While one specific implementation of a tape drive is shown in FIG. 1, it should be noted that the embodiments described herein may be implemented in the context of any type of tape drive system.

As shown, a tape supply cartridge 120 and a take-up reel 121 are provided to support a tape 122. One or more of the reels may form part of a removable cassette and are not necessarily part of the system 100. The tape drive, such as that illustrated in FIG. 1, may further include drive motor(s) to drive the tape supply cartridge 120 and the take-up reel 121 to move the tape 122 over a tape head 126 of any type.

Guides 125 guide the tape 122 across the tape head 126. Such tape head 126 is in turn coupled to a controller assembly 128 via a cable 130. The controller 128 typically controls head functions such as servo following, writing, reading, etc. The cable 130 may include read/write circuits to transmit data to the head 126 to be recorded on the tape 122 and to receive data read by the head 126 from the tape 122. An actuator 132 controls position of the head 126 relative to the tape 122.

An interface may also be provided for communication between the tape drive and a host (integral or external) to send and receive the data and for controlling the operation of the tape drive and communicating the status of the tape drive to the host, all as will be understood by those of skill in the art.

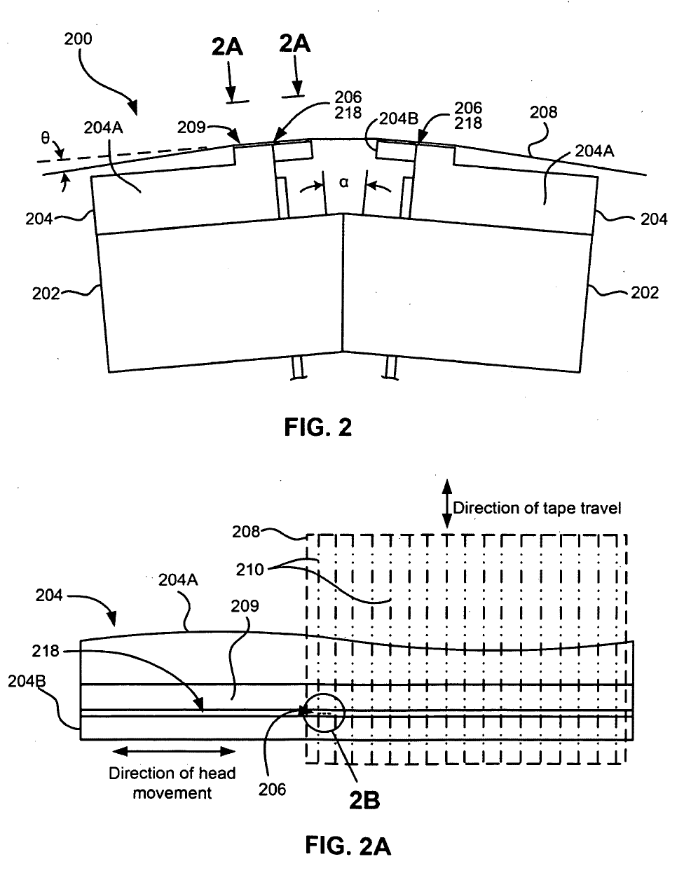

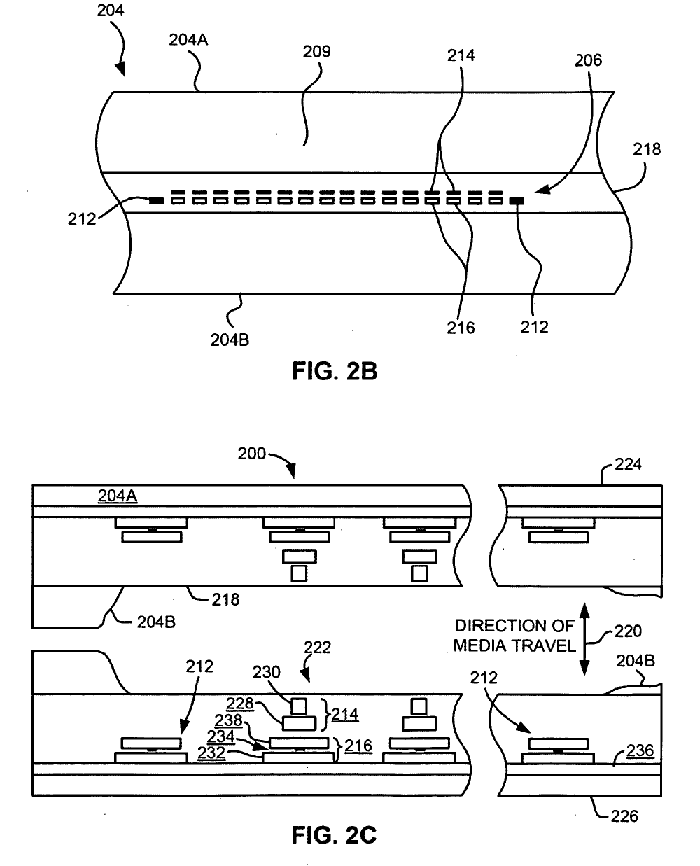

By way of example, FIG. 2 illustrates a side view of a flat-lapped, bi-directional, two-module magnetic tape head 200 which may be implemented in the context of the present invention. As shown, the head includes a pair of bases 202, each equipped with a module 204, and fixed at a small angle α with respect to each other. The bases are typically “U-beams” that are adhesively coupled together. Each module 204 includes a substrate 204A and a closure 204B with a gap 218 comprising readers and/or writers 206 situated therebetween. In use, a tape 208 is moved over the modules 204 along a media (tape) bearing surface 209 in the manner shown for reading and writing data on the tape 208 using the readers and writers. The wrap angle θ of the tape 208 at edges going onto and exiting the flat media support surfaces 209 are usually between ⅛ degree and 4½ degrees.

The substrates 204A are typically constructed of a wear resistant material, such as a ceramic. The closures 204B made of the same or similar ceramic as the substrates 204A.

The readers and writers may be arranged in a piggyback configuration. The readers and writers may also be arranged in an interleaved configuration. Alternatively, each array of channels may be readers or writers only. Any of these arrays may contain one or more servo readers.

FIG. 2A illustrates the tape bearing surface 209 of one of the modules 204 taken from Line 2A of FIG. 2. A representative tape 208 is shown in dashed lines. The module 204 is preferably long enough to be able to support the tape as the head steps between data bands.

In this example, the tape 208 includes 4-22 data bands, e.g., with 16 data bands and 17 servo tracks 210, as shown in FIG. 2A on a one-half inch wide tape 208. The data bands are defined between servo tracks 210. Each data band may include a number of data tracks, for example 96 data tracks (not shown). During read/write operations, the elements 206 are positioned within one of the data bands. Outer readers, sometimes called servo readers, read the servo tracks 210. The servo signals are in turn used to keep the elements 206 aligned with a particular track during the read/write operations.

FIG. 2B depicts a plurality of read and/or write elements 206 formed in a gap 218 on the module 204 in Circle 2B of FIG. 2A. As shown, the array of elements 206 includes, for example, 16 writers 214, 16 readers 216 and two servo readers 212, though the number of elements may vary. Illustrative embodiments include 8, 16, 32, and 64 elements per array 206. A preferred embodiment includes 32 readers per array and/or 32 writers per array. This allows the tape to travel more slowly, thereby reducing speed-induced tracking and mechanical difficulties. While the readers and writers may be arranged in a piggyback configuration as shown in FIG. 2B, the readers 216 and writers 214 may also be arranged in an interleaved configuration. Alternatively, each array of elements 206 may be readers or writers only, and the arrays may contain one or more servo readers 212. As noted by considering FIGS. 2 and 2A-B together, each module 204 may include a complementary set of elements 206 for such things as bi-directional reading and writing, read-while-write capability, backward compatibility, etc.

FIG. 2C shows a partial tape bearing surface view of complimentary modules of a magnetic tape head 200 according to one embodiment. In this embodiment, each module has a plurality of read/write (R/W) pairs in a piggyback configuration formed on a common substrate 204A and an optional electrically insulative layer 236. The writers, exemplified by the write head 214 and the readers, exemplified by the read head 216, are aligned parallel to a direction of travel of a tape medium thereacross to form an R/W pair, exemplified by the R/W pair 222.

Several R/W pairs 222 may be present, such as 8, 16, 32 pairs, etc. The R/W pairs 222 as shown are linearly aligned in a direction generally perpendicular to a direction of tape travel thereacross. However, the pairs may also be aligned diagonally, etc. Servo readers 212 are positioned on the outside of the array of R/W pairs, the function of which is well known.

Generally, the magnetic tape medium moves in either a forward or reverse direction as indicated by arrow 220. The magnetic tape medium and head assembly 200 operate in a transducing relationship in the manner well-known in the art. The piggybacked MR head assembly 200 includes two thin-film modules 224 and 226 of generally identical construction.

Modules 224 and 226 are joined together with a space present between closures 204B thereof (partially shown) to form a single physical unit to provide read-while-write capability by activating the writer of the leading module and reader of the trailing module aligned with the writer of the leading module parallel to the direction of tape travel relative thereto. When a module 224, 226 of a piggyback head 200 is constructed, layers are formed in the gap 218 created above an electrically conductive substrate 204A (partially shown), e.g., of AlTiC, in generally the following order for the R/W pairs 222: an insulating layer 236, a first shield 232 typically of an iron alloy such as NiFe (permalloy), CZT or Al—Fe—Si (Sendust), a sensor 234 for sensing a data track on a magnetic medium, a second shield 238 typically of a nickel-iron alloy (e.g., 80/20 Permalloy), first and second writer pole tips 228, 230, and a coil (not shown).

The first and second writer poles 228, 230 may be fabricated from high magnetic moment materials such as 45/55 NiFe. Note that these materials are provided by way of example only, and other materials may be used. Additional layers such as insulation between the shields and/or pole tips and an insulation layer surrounding the sensor may be present. Illustrative materials for the insulation include alumina and other oxides, insulative polymers, etc.

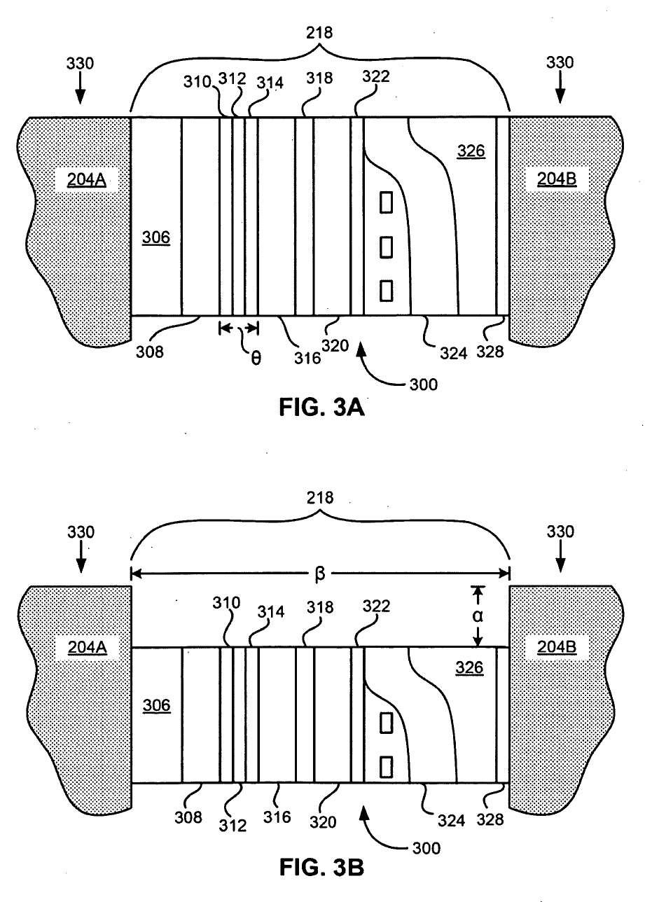

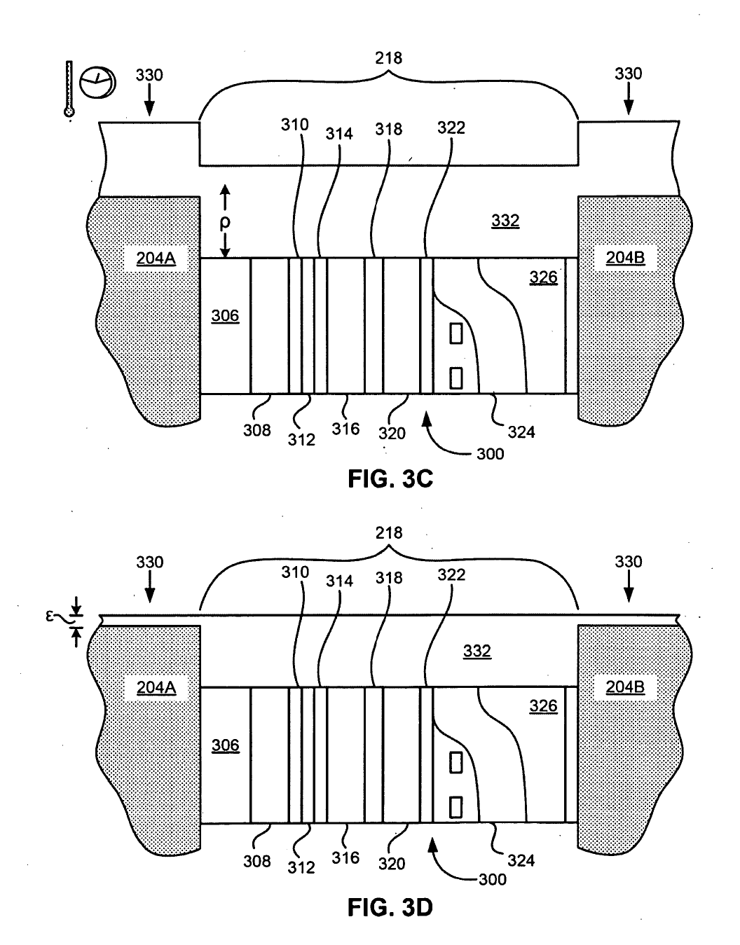

Now referring to FIGS. 3A-3D, a gap 218 is shown according to one embodiment. The substrate 204A and closure 204B may form portions of an air bearing surface (ABS) or a tape bearing surface (TBS), and may further define a thin film region 300 which may include multiple thin films which may reside in a gap, such as gap 218 shown in FIG. 3A. The gap 218 may include an array of transducers, including anisotropic magnetoresistive (AMR), giant magnetoresistive (GMR), tunneling magnetoresistive (TMR), or colossal magnetoresistive (CMR) sensors and/or writers, each separated by sufficient insulator layers, shield layers, and pole layers so that the array of transducers may function as readers and/or writers in read or write operations when used in a magnetic head. Moreover, any of the sensors may have a current-in-plane (CIP) or current-perpendicular-to-plane (CPP) configuration.

For exemplary purposes, in FIGS. 3A-3D several of these thin films are identified, such as: undercoat insulation 306, first shield 308 which may be insulated from MR sensors 312 by any number of thin films 310, and a second shield 316 which may be insulated form sensors 312 by any number of thin films 314, including at least one insulator layer. In other approaches, the shields 308, 316 serve as the leads for the sensors 312. An non-insulating (or insulating) layer 318 may separate a second shield 316 from a first pole 320. Another layer 322, often forming the write transducer gap, may separate the first pole 320 from a second pole 324 in the gap region. An overcoat insulator layer 326 may be followed by a bondline 328 near the closure 204B. There may also be other thin films and the overall design and ordering of these thin films is for illustrative purposes only, and in no way should limit the invention, nor should the inclusion of the substrate 204A and closure 204B in this description. The gap 218 may be comprised of more or less layers than is described in this example, and additional layers not mentioned here may be included to expand, adjust, or limit the functionality of the sensor array 312. Also, additional sensor arrays 312 may be included in the gap 218.

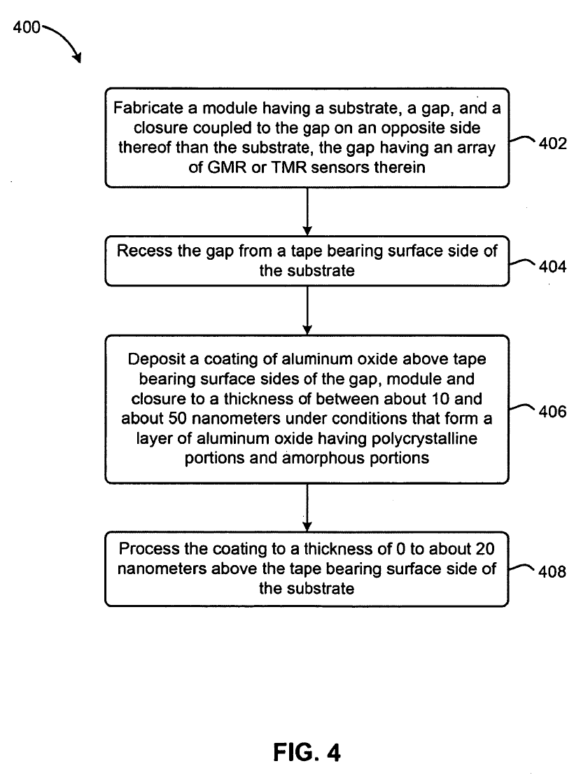

FIGS. 3A-3D in conjunction with FIG. 4 may be used to describe a method 400 according to one embodiment for fabricating a magnetic head. As an option, the present method 400 may be implemented in the context of the functionality and architecture of FIGS. 1, 2, 2A, 2B, and 2C. Of course, the method 400 may be carried out in any desired environment. It should be noted that the aforementioned definitions may apply during the present description.

In FIG. 3A, a module is formed having a substrate 204A, a gap 218, and a closure 204B coupled to the gap 218 on an opposite side thereof than the substrate 204A, the gap 218 having an array 312 of GMR or TMR sensors therein. Now referring to FIG. 4, this is shown as operation 402.

In other embodiments, the array 312 may include AMR and CMR sensors. Also, other thin film layers may be included to shield and insulate the transducers so that they can be used as writers or readers in a magnetic head.

Now referring to FIGS. 3B and 4, the gap 218 is recessed from a tape bearing surface side 330 of the substrate 204A. The distance α that the gap 218 is recessed may depend on the subsequent coating wear resistance and gap width β. In FIG. 4, this is shown as operation 404.

Preferably, the gap 218 may be recessed by a distance a of between about 10 nm. and about 50 nm., more preferably between about 20 nm. and about 40 nm. However, more or less recession may be used depending on the individual characteristics of the gap 218, coating, and magnetic head.

In some embodiments, the gap 218 may be recessed using mechanical or chem-mechanical processing, milling, etching, and other techniques which are used in the art of thin film processing, as will be understood by those having ordinary skill in the art.

In one particularly preferred embodiment, the gap 218 is recessed using plasma sputtering or ion-milling, techniques used in the art of thin film processing, as would be understood by those having ordinary skill in the art.

In another particularly preferred embodiment, ion-milling is performed progressively to achieve a surface-shorting resistant profile. In other words, the ion-milling is performed until the gap 218 has been recessed to a distance a where the movement of tape over the magnetic head will not create bridging between the thin film layers (308, 310, 312, . . . , 324) in the thin film region 300, a condition that may cause the sensor and/or magnetic head to short circuit and become inoperable.

Now referring to FIGS. 3C and 4, a coating 332 of aluminum oxide is deposited above the tape bearing surface sides 330 of the gap 218, module and closure 204B to a thickness ρ of between about 10 nm. and about 50 nm., preferably 50 nm., under conditions that form a layer of aluminum oxide having polycrystalline portions and amorphous portions. It has been surprisingly found that by coating portions of the magnetic head with aluminum oxide with a certain thickness and under certain conditions, the aluminum oxide forms a harder coating that is better able to protect the surfaces of the magnetic head from erosion and degradation through use and time.

Another embodiment includes vacuum coating the magnetic head, preferably immediately or as soon as possible after the gap 218 ion-milling, plasma sputtering, mechanical or chem-mechanical processing. The coating may be applied to the tape bearing surface sides of the gap 218, module and closure 204B using ion beam deposition (IBD) or atomic beam deposition (ABD), or any other technique which can produce a layer of aluminum oxide with a controlled thickness. Those skilled in the art, now apprised of the new and nonobvious characteristics of the coating, should be able to reproduce such layer without undue experimentation.

The vacuum coating is preferably performed in the same chamber as is used to recess the gap 218. Further, the coating 332 may be comprised of low argon-containing, approximately stoichiometric aluminum oxide. In addition, the aluminum oxide used in the coating 332 may be natively amorphous.

Preferably, the aluminum oxide coating 332 may have an oxygen to aluminum ratio of 3:2 or slightly greater than 3:2.

In another embodiment, the aluminum oxide coating 332 may have less than approximately one atomic percentage of impurities, where impurities include argon, nitrogen, and other gases.

In yet another embodiment, the aluminum oxide coating 332 may optionally have an adhesion layer between the coating 332 and the gap 218, such as silicon nitride.

Now referring to FIGS. 3D and 4, the coating 332 may be processed to a thickness E of between about 0 nm. and about 20 nm. above the tape bearing surface side 330 of the substrate 204A. This is shown as operation 408 in FIG. 4. If the coating 332 is processed to a thickness of 0 nm., then the coating is substantially removed from the tape bearing surface side 330 of the substrate 204A, closure 204B, and gap 218.

Preferably, the coating 332 is processed using kiss lapping, a process known in the art of thin film processing by those having ordinary skill in the art. This processing may result in a damascene-type finish above the gap 218. A preferred processing may be performed in which the coating is lapped using aluminum oxide pads in an environment of 100% ethylene glycol with substantially no water present.

In another embodiment, the magnetic head having a recessed gap 218 may have a low or negligible level of implanted argon after processing is completed, including milling, etching, polishing, etc.

Preferably, the transducers which include sensors in the array 312 have certain magnetic characteristics due to material selection, such as spin valve layers comprised of IrMn thin films, and free layers comprised of permalloy (NiFe) with a nickel to iron ratio having higher than 80% nickel, such as about 84:16. Also, the magnetostriction (λ) of the free layer is preferably about −0.5×10⁻⁷ to about −3.0×10⁻⁶.

A TMR transducer preferably has read widths of about 0.1 micron to about 2.5 micron, and may be approximately 1.0 micron tall or less. The read gap (θ, FIG. 3A) for all types of sensors (AMR, GMR, TMR, CMR, etc.) is preferably less than about 0.16 micron, e.g., 0.15 micron or less.

Now referring to FIG. 3D, a magnetic head, such as 200 in FIG. 2, may be comprised of a module having a substrate 204A and a gap 218, the gap 218 having an array of transducers 312 therein, wherein the gap 218 is recessed from a plane extending across a tape bearing surface side 330 of the substrate 204A. Also, the magnetic head may comprise a coating 332 of aluminum oxide above at least a tape bearing surface side 330 of the gap 218, the aluminum oxide having polycrystalline portions and amorphous portions. In a preferred embodiment, the magnetic head further comprises a closure 204B positioned on an opposite side of the gap 218 than the substrate 204A.

In other embodiments, the array of transducers 312 includes AMR, GMR, TMR, and CMR sensors.

In a particularly preferred embodiment, a magnetic head may comprise modules processed with method 400. In addition, the magnetic head preferably has restricted module spacing and wrap angle to facilitate high areal density operation.

Preferably, the gap 218 is recessed about 20 to about 40 nm. from the tape bearing surface 330. In addition, a ratio of oxygen to aluminum in the aluminum oxide is about 3:2 to about 3.5:2. Further, the aluminum oxide coating 332 may have less than about 1% atomic percent of impurities that are not aluminum and oxygen, such as argon, nitrogen, etc.

In another embodiment, the magnetic head further comprises an adhesion layer between the coating 332 and the gap 218. In addition, a thickness of the coating 332 above the tape bearing surface side 330 of the gap 218 may be about 20 nm. to about 60 nm.

In a magnetic head which comprises GMR sensors in the array of transducers 312, free layers of the sensors may comprise NiFe having a Ni:Fe ration higher than about 81:19, wherein a magnetostriction of each of the free layers of the sensors is between about −0.5×10⁻⁷ to about −3.0×10⁻⁶, wherein read gaps of the sensor are less than about 0.16 micron.

In a magnetic head which comprises TMR sensors in the array of transducers 312, the TMR sensors may each have a read width of about 0.1 micron to about 2.5 micron, more preferably about 0.25 to about 1.0 microns, wherein the TMR sensors may be about square, and/or approximately 1.0 micron tall or less.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

What is claimed is:

1. A magnetic head, comprising:
a module having a substrate and a gap, the gap having an array of transducers therein, wherein the gap is recessed from a plane extending across a tape bearing surface side of the substrate; and
a coating of aluminum oxide above at least a tape bearing surface side of the gap, the aluminum oxide having polycrystalline portions and amorphous portions.

2. A head as recited in claim 1, wherein the gap is recessed about 10 to about 50 nanometers from the tape bearing surface.

3. A head as recited in claim 1, wherein a ratio of oxygen to aluminum in the aluminum oxide is about 3 to 2 to about 3.5 to 2.

4. A head as recited in claim 1, wherein the coating has less than about 1% atomic percent of impurities that are not aluminum and oxygen.

5. A head as recited in claim 1, further comprising an adhesion layer between the coating and the gap.

6. A head as recited in claim 1, wherein a thickness of the coating above the tape bearing surface side of the gap is about 20 to about 60 nanometers.

7. A head as recited in claim 1, wherein the module further includes a closure positioned on an opposite side of the gap than the substrate.

8. A head as recited in claim 1, wherein the transducers comprise GMR sensors.

9. A head as recited in claim 8, wherein free layers of the sensors comprise NiFe having a Ni:Fe ratio higher than 81:19, wherein a magnetostriction of each of the free layers of the sensors is between about −0.5×10⁻⁷ to about −3.0×10⁻⁶, wherein read gaps of the sensor are about 0.15 micron or less.

10. A head as recited in claim 1, wherein the transducers comprise TMR sensors.

11. A head as recited in claim 10, wherein the TMR sensors each have a read width of about 0.1 to about 2.5 microns, wherein the TMR sensors are about 1.0 micron tall or less.

12. A magnetic head, comprising:
a module having a substrate, a gap, and a closure coupled to the gap on an opposite side thereof than the substrate, the gap having an array of GMR or TMR sensors therein, wherein the gap is recessed from a plane, extending across a tape bearing surface side of the substrate; and
a coating of aluminum oxide above at least a tape bearing surface side of the gap, the aluminum oxide having polycrystalline portions and amorphous portions,
wherein the gap is recessed about 10 to about 50 nanometers,
wherein a ratio of oxygen to aluminum in the aluminum oxide is about 3 to 2 to about 3.5 to 2,
wherein the coating has less than about 1% atomic percent of impurities that are not aluminum and oxygen,
wherein a thickness of the coating above the tape bearing surface side of the gap is about 20 to about 60 nanometers.

13. A head as recited in claim 12, wherein the sensors are GMR sensors, wherein free layers of the sensors comprise NiFe having a Ni:Fe ratio higher than 81:19, wherein a magnetostriction of each of the free layers of the sensors is between about −0.5×10⁻⁷ to about −3.0×10⁻⁶, wherein read gaps of the sensor are about 0.15 micron or less.

14. A head as recited in claim 12, wherein the sensors are TMR sensors, wherein the TMR sensors each have a read width of about 0.1 to about 2.5 microns, wherein the TMR sensors are about 1.0 micron tall or less.

15. A method for fabricating a magnetic head, comprising:
forming a module having a substrate, a gap, and a closure coupled to the gap on an opposite side thereof than the substrate, the gap having an array of GMR or TMR sensors therein;
recessing the gap from a tape bearing surface side of the substrate;
depositing a coating of aluminum oxide above tape bearing surface sides of the gap, module and closure to a thickness of between about 10 and about 50 nanometers under conditions that form a layer of aluminum oxide having polycrystalline portions and amorphous portions;
recessing the coating to a thickness of 0 to about 20 nanometers above the tape bearing surface side of the substrate.

16. A method as recited in claim 15, wherein the coating is processed using kiss lapping.

17. A method as recited in claim 15, wherein the coating is deposited using at least one of ion beam deposition and atomic layer deposition.

18. A method as recited in claim 15, wherein the sensors are GMR sensors, wherein free layers of the sensors comprise NiFe having a Ni:Fe ratio higher than 81:19, wherein a magnetostriction of each of the free layers of the sensors is between about −0.5×10⁻⁷ to about −3.0×10⁻⁶, wherein read gaps of the sensor are about 0.15 micron or less.

19. A method as recited in claim 15, wherein the sensors are TMR sensors, wherein the TMR sensors each have a read width of about 0.1 to about 2.5 microns, wherein the TMR sensors are about 1.0 micron tall or less.

20. A method for fabricating a magnetic head, comprising:
forming a module having a substrate, a gap, and a closure coupled to the gap on an opposite side thereof than the substrate, the gap having an array of GMR or TMR sensors therein;
recessing the gap about 20 to about 40 nanometers from a plane extending across a tape bearing surface side of the substrate;
depositing a coating of aluminum oxide above tape bearing surface sides of the gap, module and closure to a thickness of between about 10 and about 50 nanometers under conditions that form a layer of aluminum oxide having polycrystalline portions and amorphous portions;
recessing the coating to a thickness of 0 to about 20 nanometers above the tape bearing surface side of the substrate,
wherein a ratio of oxygen to aluminum in the aluminum oxide is about 3 to 2 to about 3.5 to 2,
wherein the coating has less than about 1% atomic percent of impurities that are not aluminum and oxygen.
